(19) United States
(12) Patent Application Publication
(10) Pub. No.: US 2007/0096150 A1
(43) Pub. Date: May 3, 2007

(54) HETEROJUNCTION BIPOLAR TRANSISTOR

(75) Inventor: Takatoshi IKEDA, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/554,221

(22) Filed: Oct. 30, 2006

(30) Foreign Application Priority Data
Nov. 1, 2005 (JP) 2005/318896

(51) Int. Cl. H01L 31/00

(52) U.S. Cl. 257/197

(57) ABSTRACT

The present invention has an object to provide a heterojunction bipolar transistor which can eliminate band discontinuities (ΔEc) in a bottom part of the conduction band in a heterojunction of a base-emitter, and the heterojunction bipolar transistor includes a substrate made of semi-insulating GaAs; and an epitaxial layer which matches the lattice of the substrate, wherein said epitaxial layer includes: a sub-collector layer made of n⁺-GaAs, a collector layer made of n-GaAs, a base layer made of p⁺-GaPSb and an emitter layer made of InGaP with the same electron affinity as the GaPSb and a larger band gap energy than GaPSb.

### BACKGROUND OF THE INVENTION

(1) Field of the Invention

The present invention relates to a heterojunction bipolar transistor, and particularly to an epitaxial substrate which makes up a heterojunction bipolar transistor.

(2) Description of the Related Art

The heterojunction bipolar transistor (below abbreviated as HBT) can perform a lower distortion amplification operation and a simpler power supply operation in comparison to a field-effective transistor, and in recent years has become a key device in mobile communications and optical communications systems.

In order to obtain high-current gain in a homojunction bipolar transistor, the efficiency for the carrier injection from the emitter layer to the base layer must be increased, and the donor concentration of the emitter layer must be increased to greater than the accepter concentration of the base layer. Thus impurities with a high degree of concentration cannot be doped into the base layer. On the other hand, in an HBT, since a band discontinuity (Δ Ev) is generated in the top part of the valence band by utilizing a material with a band gap energy larger than the base layer for the emitter layer, a structure for suppressing an inflow of holes in the base layer into the emitter layer can be realized (see for example Japanese Laid-Open Patent Application No. 2004-71669). Thus, in an HBT, a high current gain can be maintained and limitations related to doping concentration, as in a homojunction bipolar transistor, are eliminated. Accordingly, since a high concentration impurity can be doped into the base layer, base resistance can be kept low even if the thickness of the base layer is thinned, and therefore high frequency properties can be improved by decreasing the input resistance.

A sectional view of a conventional GaAs-type HBT is illustrated in FIG. 1.

In this HBT, a subcollector layer 502 made of n⁺-GaAs (thickness=6000 Å, concentration of n-type impurity=5×10¹⁸ cm⁻³), a collector layer 503 made of n⁻-GaAs (thickness=6000 Å, concentration of n-type impurity=5×10¹⁶ cm⁻³), a base layer 504 made of p⁺-GaAs (thickness=1000 Å, concentration of p-type impurity=4×10¹⁹ cm⁻³), an emitter layer 505 made of n-InGaP matching the lattice constant of GaAs (thickness=300 Å concentration of n-type impurity=3×10¹⁷ cm⁻³), an emitter layer 506 made of n-GaAs (thickness=500 Å, concentration of n-type impurity=3×10¹⁸ cm⁻³), an emitter layer 507 made of n⁺-GaAs (thickness=500 Å, concentration of n-type impurity=5×10¹⁸ cm⁻³), a grading layer 508 made of n⁺-InGaAs (thickness=500 Å, concentration of n-type impurity=changes from 0.5×10¹⁹ cm⁻³ to 1×10¹⁹ cm⁻³), and a cap layer 509 made of n⁺-InGaAs (thickness=500 Å, concentration of n-type impurity=1×10¹⁹ cm⁻³) are stacked sequentially on a substrate 501 made of semi-insulating GaAs and form an epitaxial layer as an HBT structure. A collector electrode 510, a base electrode 511 and an emitter electrode 512 are formed during the manufacturing process of the transistor on the subcollector layer 502, the base layer 504 and the cap layer 509 respectively. Note that an HBT in which the emitter layer 505 is made of InGaP was exemplified as a conventional HBT, however the emitter layer 505 is also sometimes made of AlGaAs, which has a larger band gap energy than GaAs.

### SUMMARY OF THE INVENTION

In the HBT shown as a conventional example in FIG. 1, InGaP is used in the emitter layer 505. InGaP has a higher band gap energy compared to GaAs, which makes up the base layer 504. Accordingly, an example energy band diagram in the heterojunction (the energy band diagram of the A-A′ line in FIG. 1) is shown in FIG. 2. From FIG. 2 it is shown that when an emitter layer is made of a material that has a higher band gap energy than a material which makes up the base layer, not only will ΔEv generate, a spike-shaped band discontinuity (ΔEc) in the bottom part of a conduction band will also occur at the hetero interface of the base layer and the emitter layer. In other words, it is shown that an ΔEv of approximately 0.3 eV, and an ΔEc of approximately 0.2 eV generates in a GaAs/InGaP heterojunction. Here, in order to improve the current gain as above, it is preferable that an ΔEv which suppresses the reverse influx of holes in the base layer into the emitter layer is as large as possible. Whereas in order to reduce the offset voltage, which is one of the electrical characteristics of the transistor, it is preferable that the spike-shaped ΔEc, which functions as a barrier to electron injection from the emitter layer into the base layer, be made as small as possible or omitted.

Thus, the present invention takes as its first object providing a heterojunction bipolar transistor which can omit band discontinuities (ΔEc) in the bottom part of the conduction band in the heterojunction of the base-emitter, in consideration of the problems above.

A second object is to provide a heterojunction bipolar resistor which can increase band discontinuities (ΔEv) in the top part of the valence band in the heterojunction of the base-emitter.

In order to solve the problems above, the heterojunction bipolar transistor in the present invention includes a substrate made of semi-insulating GaAs; and an epitaxial layer which lattice-matches the substrate, including: a base layer made of GaPSb; and an emitter layer made of a semiconductor material that has the same electron affinity as the GaPSb and a band gap energy larger than GaPSb. Here, the emitter layer may be made of InGaP. Also, the composition of the GaPSb which makes up the base layer may be GaPₓSb₁₋ₓ, where 0.30≦X≦0.35, and the emitter layer may be made of one of AlGaAs, AlGaInP and AlGaPSb.

With this configuration, GaPSb, which matches lattices with GaAs, is utilized as a semiconductor material which makes up the base layer instead of utilizing GaAs in the same way as a conventional GaAs HBT which is made up of GaAs. Accordingly, a spike-shaped discontinuity does not generate in the conduction band (ΔEc) of the base-emitter hetero interface and discontinuities in the valence band (ΔEv) increase. As a result, since electrons arrive in the base layer from the emitter layer without being affected by the ΔEc, and the reverse influx of holes from the base layer into the emitter layer is suppressed, an HBT with a small offset voltage and a high current gain can be realized.

Also, the epitaxial layer may further include a collector layer made of GaPSb.

With this configuration, the collector layer is made of GaPSb and the base collector interface is a homojunction made from GaPSb/GaPSb which include some V group elements. As a result, in the manufacturing process, exchanges of raw material sources which are easily mixable do not occur compared to when the collector layer is made of GaAs and the base collector interface is a homojunction made from GaPSb/GaAs. Therefore, it becomes possible to make an abrupt base collector interface without mixed elements, and form a satisfactory pn junction and a base-collector interface with few electron hole recombinations in the interface.

According to the present invention, since band discontinuities (ΔEc) in the bottom part of the conduction band in the base-emitter hetero interface are eliminated, an HBT can be realized which is not influenced by the ΔEc while operating. In other words, an HBT with a small offset voltage can be achieved.

Also, band discontinuities in the top part of the valence band increase at the base-emitter hetero interface and the current gain improves compared to a conventional HBT in which the base layer is made of GaAs. In addition, the temperature dependence of the current gain decreases.

Also, since the base collector interface is a homojunction not made from GaPSb/GaAs, but instead from GaPSb/GaPSb which includes some V group elements, it becomes possible to compose an abrupt base collector interface without mixed elements, and as a result, electron hole recombinations in the interface can be reduced.

### FURTHER INFORMATION ABOUT TECHNICAL BACKGROUND TO THIS APPLICATION

The disclosure of Japanese Patent Application No. 2005-318896 filed on Nov. 1, 2005 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a sectional view of a conventional HBT.

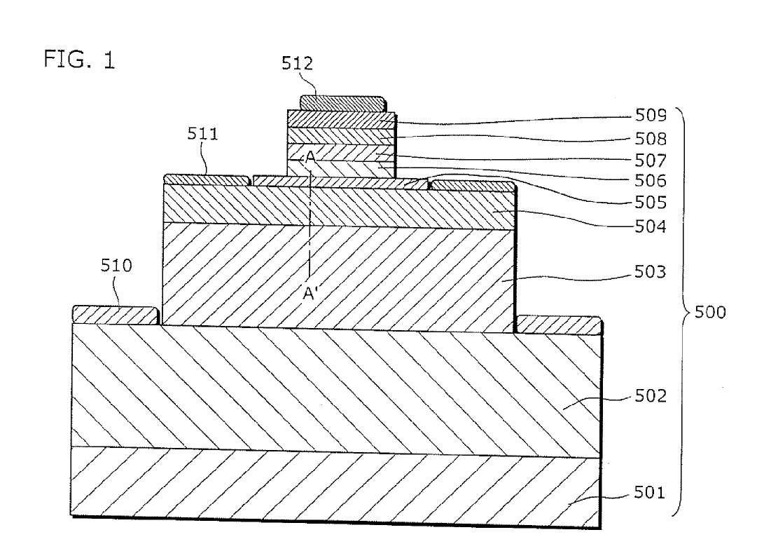

FIG. 2 is an energy band diagram for the heterojunction in the conventional HBT (an energy band diagram for the A-A′ line in FIG. 1).

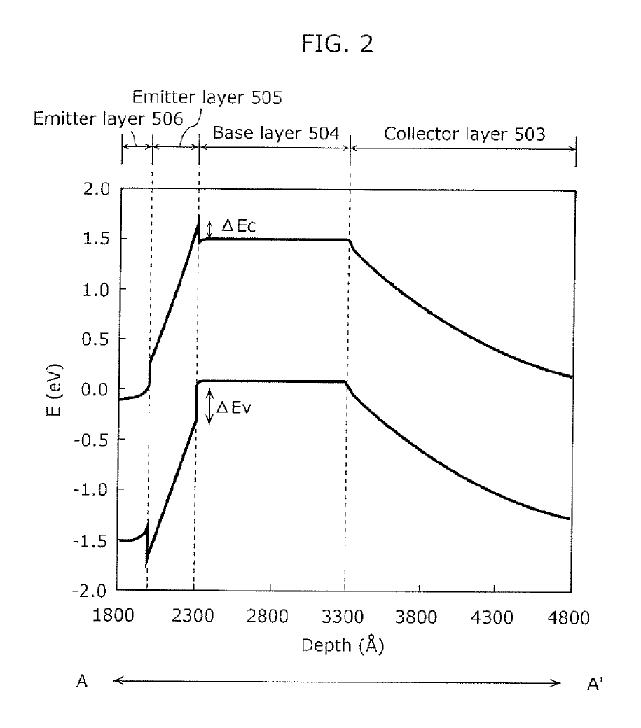

FIG. 3 is a sectional view of the HBT in the first embodiment of the present invention.

FIG. 4 is an energy band diagram for the heterojunction of the HBT in the first embodiment (an energy band diagram for the A-A′ line in FIG. 3).

FIG. 5 is a sectional view for the HBT in the second embodiment of the present invention.

FIG. 6 is an energy band diagram for the heterojunction of the HBT in the second embodiment (an energy band diagram for the A-A′ line in FIG. 5).

### DESCRIPTION OF THE PREFERRED EMBODIMENT(S)

Below, a Heterojunction Bipolar Transistor (HBT) in the embodiments of the present invention is described with reference to diagrams.

### First Embodiment

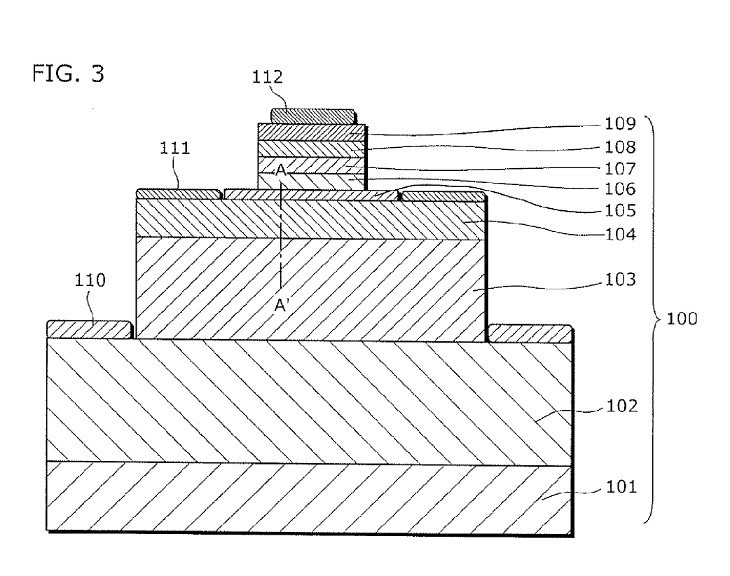

FIG. 3 is a sectional view of the HBT in the present embodiment.

In this HBT, a subcollector layer 102 made of n⁺-GaAs (thickness=6000 Å, concentration of n-type impurity=5×10¹⁸ cm⁻³), a collector layer 103 made of n-GaAs (thickness=6000 Å, concentration of n-type impurity=5×10¹⁶ cm⁻³), a base layer 104 made of p⁺-GaPSb in which carbon is doped (thickness=1000 Å, concentration of p-type impurity=4×10¹⁹ cm⁻³), an emitter layer 105 made of n-InGaP which matches the lattice constant of GaAs (thickness=300 Å, concentration of n-type impurity=3×10¹⁷ cm⁻³), an emitter layer 106 made of n-GaAs (thickness—500 Å, concentration of n-type impurity=3×10¹⁸ cm⁻³) an emitter layer 107 made of n⁺-GaAs (thickness=500 Å, concentration of n-type impurity=5×10¹⁸ cm⁻³), a grading layer 108 made of n⁺-InGaAs (thickness=500 Å, concentration of n-type impurity=changes from 0.5×10¹⁹ cm⁻³ to 1×10¹⁹ cm⁻³), and a cap layer 109 made of n⁺-InGaAs (thickness=500 Å, concentration of n-type impurity=1×10¹⁹ cm⁻³) are stacked sequentially on a substrate 101 made of semi-insulating GaAs by utilizing epitaxial crystal growth technology, and form an epitaxial layer 100 as an HBT structure. A collector electrode 110, a base electrode 111 and an emitter electrode 112 are formed during the manufacturing process on the subcollector layer 102, the base layer 104 and the cap layer 109 respectively. Also, the composition of GaPSb is assumed to be GaPₓSb₁₋ₓ (0.30≦X≦0.35) so that GaPSb, which makes up the base layer 104, reaches a lattice constant which matches the lattice of GaAs.

Note that the emitter layer 105 is made of InGaP. However, the present invention is not limited to InGaP, and any other materials can be used if they have the same electron affinity as GaPSb, the semiconductor material which makes up the emitter layer 105, and a larger band gap energy than GaPSb. It goes without saying that even if the base layer 104 is made of for example AlGaAs, AlGaInP or AlGaPSb and so on, the same effect can be obtained.

In addition, the emitter layer 106 and the emitter layer 107 are made of GaAs. However, the emitter layer 106 and the emitter layer 107 may each be made of GaPSb.

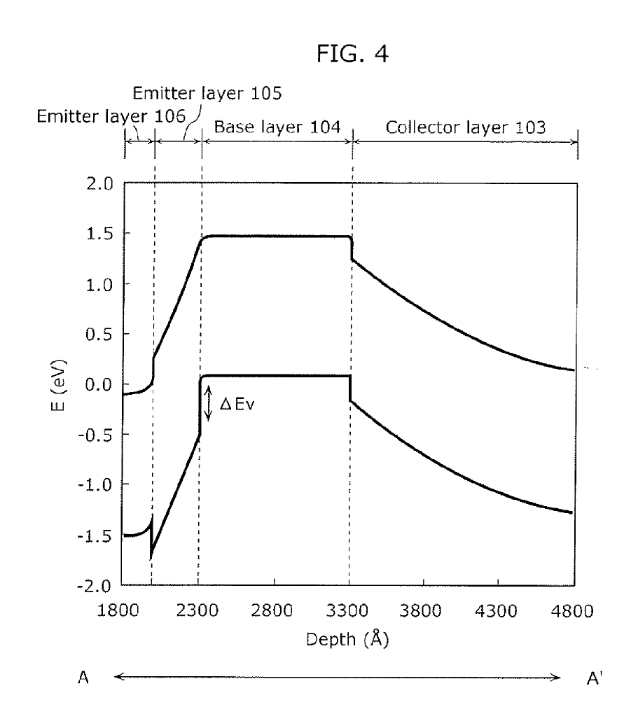

FIG. 4 shows an energy band diagram for the heterojunction of the HBT in the present embodiment (an energy band diagram for the A-A′ line in FIG. 3).

From FIG. 4 it is shown that a band discontinuity (ΔEc) in the conduction band is eliminated in the base-emitter hetero interface, and in the valence band, band discontinuities larger than a conventional HBT (ΔEv=approximately 0.6 eV) generate.

According to the HBT in the present embodiment as above, the base layer 104 is made of GaPSb and the emitter layer 105 is made of InGaP, InGaP having the same electron affinity as GaPSb which makes up the base layer, and a larger band gap energy than GaPSb. As a result, band discontinuities (ΔEc) in the bottom part of the conduction band in the base-emitter hetero interface are eliminated and electrons injected from the emitter layer into the base layer can reach the base layer unaffected by ΔEc. Thus, an HBT which is unaffected by ΔEc while operating can be realized. In other words, an HBT with a small offset voltage is realizable.

Additionally, according to the HBT in the present embodiment, GaPSb (Eg=1.39 eV) which makes up the base layer 104 has about the same energy gap as GaAs (Eg=1.42 eV). Thus, compared to a conventional HBT with a base layer made of GaAs, ΔEc decreases and band discontinuities (ΔEv) increase in the top part of the valence band in the base-emitter hetero interface. As an effect of the large ΔEv, the reverse influx of holes in the base layer into the emitter layer is suppressed and the current gain improves. Also, with the rise in temperature, electric current, caused by the reverse influx of holes in the base layer into the emitter layer, increases and the current gain decreases, but since this kind of electric current decreases as a result of the large ΔEv, the temperature dependence of the current gain decreases compared to when the base layer is made of GaAs.

### Second Embodiment

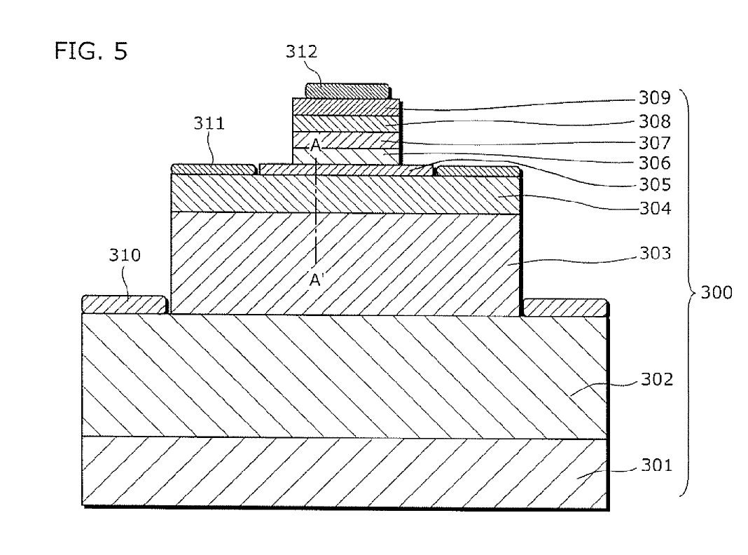

FIG. 5 is a sectional view of the HBT in the present embodiment.

In this HBT, a subcollector layer 302 made of n⁺-GaPSb (thickness=6000 Å, concentration of n-type impurity=5×10¹⁸ cm⁻³), a collector layer 303 made of n-GaPSb (thickness=6000 Å, concentration of n-type impurity=5×10¹⁶ cm⁻³), a base layer 304 made of p⁺-GaPSb in which carbon is doped (thickness=1000 Å, concentration of p-type impurity=4×10¹⁹ cm⁻³), an emitter layer 305 made of n-InGaP matching the lattice constant of GaAs (thickness=300 Å, concentration of n-type impurity=3×10¹⁷ cm⁻³), an emitter layer 306 made of n-GaAs (thickness=500 Å, concentration of n-type impurity=3×10¹⁸ cm⁻³), an emitter layer 307 made of n⁺-GaAs (thickness=500 Å/concentration of n-type impurity=5×10¹⁸ cm⁻³), a grading layer 308 made of n⁺-InGaAs (thickness=500 Å, concentration of n-type impurity=changes from 0.5×10¹⁹ cm⁻³ to 1×10¹⁹ cm⁻³), and a cap layer 309 made of n⁺-InGaAs (thickness=500 Å, concentration of n-type impurity=1×10¹⁹ cm⁻³) are sequentially stacked on a substrate 301 made of semi-insulating GaAs by utilizing epitaxial crystal growth technology, and form an epitaxial layer 300 as an HBT structure. A collector electrode 310, a base electrode 311 and an emitter electrode 312 are formed during the manufacturing process on a subcollector layer 302, a base layer 304 and a cap layer 309 respectively. Also, the composition of GaPSb is assumed to be GaPₓSb₁₋ₓ (0.30≦X≦0.35) so that GaPSb, which makes up the base layer 304, reaches a lattice constant which matches the lattice constant of GaAs.

Note that the emitter layer 305 is made of InGaP. However, the present invention is not limited to InGaP, and any other materials can be used if they have the same electron affinity as GaPSb, the semiconductor material which makes up the base layer 304, and a larger band gap energy than GaPSb. It goes without saying that the same effect is obtained when the emitter layer 305 is made of for example AlGaAs, AlGaInP or AlGaPSb and so on.

Also, the emitter layer 306 and the emitter layer 307 are made of GaAs. However, the emitter layer 306 and the emitter layer 307 may each be made of GaPSb.

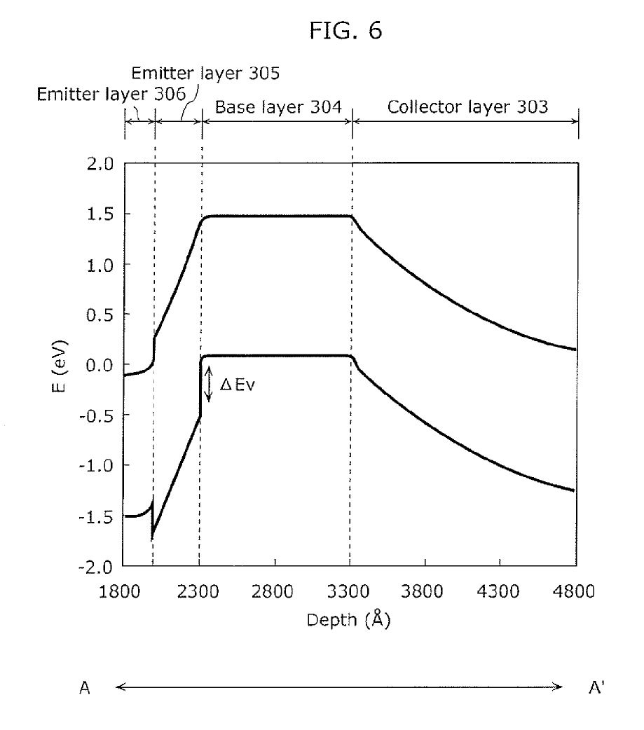

FIG. 6 shows an energy band diagram for the heterojunction of the HBT in the present embodiment (an energy band diagram for the A-A′ line in FIG. 5).

From FIG. 6 it is shown that a band discontinuity (ΔEc) is eliminated in the base-emitter hetero interface, and that in the valence band, band discontinuities larger than a conventional HBT (ΔEv=approximately 0.6 eV) generate.

According to the HBT in the present embodiment as above, the base layer 304 is made of GaPSb, and the emitter layer 305 is made of InGaP which has the same electron affinity as GaPSb, which makes up the base layer, and has a larger band gap energy than GaPSb. As a result, band discontinuities (ΔEc) in the bottom part of the conduction band in the base-emitter hetero interface can be eliminated and electrons injected into the base layer from the emitter layer can reach the base layer unaffected by ΔEc, therefore an HBT which is unaffected by ΔEc while operating can be realized. In other words, offset voltage makes a small HBT realizable.

According to the HBT in the present embodiment, GaPSb (Eg=1.39 eV), which makes up the base layer 304, has about the same energy gap as GaAs (Eg=1.42 eV). Accordingly, compared to an HBT in which the base layer is made of GaAs, ΔEc decreases and band discontinuities (ΔEv) increase in the top part of the valence band in the base-emitter hetero interface. As a result, the reverse influx of holes in the base layer into the emitter layer is suppressed by a large ΔEv, and the current gain improves. Additionally, with the rise in temperature, the electric current, which is caused by the reverse influx of holes in the base layer into the emitter, increases and the current gain decreases. Since this kind of electric current decreases as an effect of the increased ΔEv, the temperature dependence of the current gain decreases compared to when the base layer is made of GaAs.

Also, according to the HBT in the present embodiment, the collector layer 303 utilizes GaPSb, and the base collector interface is a homojunction not made from GaPSb/GaAs, but instead from GaPSb/GaPSb which includes some V group elements. As a result, in the manufacturing process, exchanges of raw material sources which are easily mixable do not occur compared to when the collector layer 303 is made of GaAs. Accordingly, it is possible to form an abrupt base collector interface without mixed elements, and thus a base collector interface with few electron hole recombinations in the interface can be produced since a satisfactory pn junction can be made compared to when the collector layer is made of GaAs.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

For example, the thickness of the semiconductor layer included in the epitaxial layer and the carrier concentration are examples and are not limited to these examples.

Also, in the embodiments, the dopant of the base layer is carbon; however the present invention is not limited to carbon as long as the dopant makes the base layer a p-type layer.

### INDUSTRIAL APPLICABILITY

The present invention can be utilized for a heterojunction bipolar transistor and especially for a mobile communications or an optical communications system.

What is claimed is:

1. A heterojunction bipolar transistor comprising:
a substrate made of semi-insulating GaAs; and
an epitaxial layer which lattice-matches said substrate,
wherein said epitaxial layer includes:
a base layer made of GaPSb; and
an emitter layer made of a semiconductor material that has the same electron affinity as the GaPSb and a band gap energy larger than GaPSb.

2. The heterojunction bipolar transistor according to claim 1,
wherein said epitaxial layer further includes a collector layer made of GaPSb.

3. The heterojunction bipolar transistor according to claim 2,
wherein said emitter layer is made of InGaP.

4. The heterojunction bipolar transistor according to claim 3,
wherein the composition of the GaPSb which makes up said base layer is GaPₓSb₁₋ₓ where 0.30≦X≦0.35.

5. The heterojunction bipolar transistor according to claim 2,
wherein the composition of the GaPSb which makes up said base layer is GaPₓSb₁₋ₓ where 0.30≦X≦0.35.

6. The heterojunction bipolar transistor according to claim 2,
wherein said emitter layer is made of one of AlGaAs, AlGaInP and AlGaPSb.

7. The heterojunction bipolar transistor according to claim 1,
wherein said emitter layer is made of InGaP.

8. The heterojunction bipolar transistor according to claim 1,
wherein the composition of the GaPSb which makes up said base layer is GaPₓSb₁₋ₓ where 0.30≦X≦0.35.

9. The heterojunction bipolar transistor according to claim 1,
wherein said emitter layer is made of one of AlGaAs, AlGaInP and AlGaPSb.
